(19) United States
(12) Patent Application Publication
(10) Pub. No.: US 2025/0098496 A1
(43) Pub. Date: Mar. 20, 2025

(54) DISPLAY DEVICE

(71) Applicant: Samsung Display Co., Ltd., Yongin-si (KR)

(72) Inventors: EUI JUNG KWON, Yongin-si (KR); SOONNYUNG PARK, Yongin-si (KR)

(21) Appl. No.: 18/799,141

(22) Filed: Aug. 9, 2024

(30) Foreign Application Priority Data
Sep. 15, 2023 (KR) 10-2023-0123020

(51) Int. Cl. H10K 59/80; H10K 59/131; H10K 59/40

(52) U.S. Cl. CPC H10K 59/879; H10K 59/131; H10K 59/40; H10K 59/8731; H10K 59/8791

(57) ABSTRACT

Provided is a display device including a display panel defining a display region and a non-display region, and including a base layer, a light-emitting element layer above the base layer and including a light-emitting element, and an organic encapsulation layer above the light-emitting element and including a protrusion protruding along a thickness direction of the display panel, at least partially overlapping the display region, and configured to refract a portion of light generated in the display region, an input-sensing unit above the display panel, and including a sensing electrode overlapping the display region, and a signal line connected to the sensing electrode, and a window above the input-sensing unit, and including an optically transparent base substrate, the input-sensing unit or the window including an optical structure overlapping the protrusion.

### CROSS-REFERENCE TO RELATED APPLICATION

This application claims priority to, and the benefit of, Korean Patent Application No. 10-2023-0123020, filed on Sep. 15, 2023, the entire contents of which are hereby incorporated by reference.

### BACKGROUND

### 1. Field

The present disclosure herein relates to a display device having an improved visibility.

### 2. Description of the Related Art

A display device may include a display panel for displaying an image, and an input-sensing unit for sensing an external input. The input-sensing unit and the display panel may be formed as one piece through a continuous process. Alternatively, the input-sensing unit may be formed through a process separate from that for the display panel, and then may be coupled to the display panel.

Recently, a structure of a flexible display device having a reduced, minimized, or bent non-display region has been suggested so as to enhance a visibility and reduce dead space. Meanwhile, when the dead space is reduced, a visibility defect such as a stain may occur in a peripheral area of a display device due to an uneven organic layer design or the like, and therefore there is a demand for a process design capable of reducing or preventing such a visibility defect.

### SUMMARY

The present disclosure provides a display device of which a visibility defect may be reduced or prevented while having reduced or minimized dead space.

One or more embodiments of the present disclosure provide a display device including a display panel defining a display region and a non-display region, and including a base layer, a light-emitting element layer above the base layer and including a light-emitting element, and an organic encapsulation layer above the light-emitting element and including a protrusion protruding along a thickness direction of the display panel, at least partially overlapping the display region, and configured to refract a portion of light generated in the display region, an input-sensing unit above the display panel, and including a sensing electrode overlapping the display region, and a signal line connected to the sensing electrode, and a window above the input-sensing unit, and including an optically transparent base substrate, the input-sensing unit or the window including an optical structure overlapping the protrusion.

The window may include a first optical structure protruding from the base substrate.

The base substrate may be integral with the first optical structure.

The window may further include a window protective layer above the base substrate, and a printed layer on the window protective layer and overlapping the non-display region.

The input-sensing unit may include a first sensing insulating layer above the encapsulation layer, a first conductive pattern layer above the first sensing insulating layer, a second sensing insulating layer above the first conductive pattern layer, and a second conductive pattern layer above the second sensing insulating layer.

The input-sensing unit may include a second optical structure below the first sensing insulating layer, and overlapping the protrusion.

The second optical structure may be in the non-display region and may have a closed curve shape surrounding the display region in plan view.

The second optical structure may include unit optical structures spaced apart from each other, and arranged in the non-display region to surround the display region in plan view.

The sensing electrode may include sensing patterns above the second sensing insulating layer, wherein the signal line is above the second sensing insulating layer.

The display device may further include an anti-reflective layer between the input-sensing unit and the window.

The display device may further include an intermediate layer between the anti-reflective layer and the window, and having a refractive index that is larger than a refractive index of the base substrate.

The input-sensing unit may further include at least one sensing insulating layer having a refractive index that is larger than a refractive index of the organic encapsulation layer.

The organic encapsulation layer may further include a flat portion overlapping the display region, and an inclined portion overlapping the non-display region, wherein the protrusion is between the flat portion and the inclined portion.

The encapsulation layer may further include a first inorganic encapsulation layer below the organic encapsulation layer, and a second inorganic encapsulation layer above the organic encapsulation layer, and contacting the first inorganic encapsulation layer.

According to one or more embodiments of the present disclosure, a display device includes a display panel defining a display region and a non-display region, and including a base layer, a light-emitting element layer above the base layer and including a light-emitting element, and an organic encapsulation layer above the light-emitting element and including a protrusion protruding along a thickness direction of the display panel and partially overlapping the display region, an input-sensing unit above the display panel, and including a sensing electrode overlapping the display region, and a signal line connected to the sensing electrode, and a window above the input-sensing unit, and including an optically transparent base substrate, and a first optical structure protruding from the base substrate in a direction adjacent to the input-sensing unit and overlapping the protrusion.

The base substrate may be integral with the first optical structure.

The display device may further include an intermediate layer between the input-sensing unit and the window, and having a refractive index that is larger than a refractive index of the base substrate.

According to one or more embodiments of the present disclosure, a display device includes a display panel defining a display region and a non-display region, and including a base layer, a light-emitting element layer above the base layer and including a light-emitting element, and an organic encapsulation layer above the light-emitting element and including a protrusion protruding along a thickness direction of the display panel and at least partially overlapping the display region, an input-sensing unit above the display panel and including a first sensing insulating layer above the encapsulation layer, a second sensing insulating layer above the first sensing insulating layer, and a second optical structure above the first sensing insulating layer and overlapping the protrusion, and a window above the input-sensing unit and including an optically transparent base substrate.

The input-sensing unit may further include a sensing electrode overlapping the display region and including sensing patterns above the second sensing insulating layer, and a signal line connected to the sensing electrode.

A refractive index of the first sensing insulating layer may be larger than a refractive index of the organic encapsulation layer.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1A is an assembled perspective view of a display device according to one or more embodiments of the present disclosure;

FIG. 1B is an exploded perspective view of a display device according to one or more embodiments of the present disclosure;

FIG. 2 is a cross-sectional view of a display device according to one or more embodiments of the present disclosure;

FIG. 3 is a plan view of a display panel according to one or more embodiments of the present disclosure;

FIG. 4 is a cross-sectional view of a display module according to one or more embodiments of the present disclosure;

FIG. 5 is a cross-sectional view of a portion of a display device according to one or more embodiments of the present disclosure;

FIG. 6 is an enlarged cross-sectional view of a portion of a display device according to one or more embodiments of the present disclosure;

FIG. 7 is a cross-sectional view of a portion of a display device according to one or more embodiments of the present disclosure;

FIG. 8 is an enlarged cross-sectional view of a portion of a display device according to one or more embodiments of the present disclosure; and

FIG. 9A and FIG. 9B are plan views of input-sensing units according to embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc.,

may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, a display device and a manufacturing method thereof according to one or more embodiments of the present disclosure will be described with reference to the accompanying drawings.

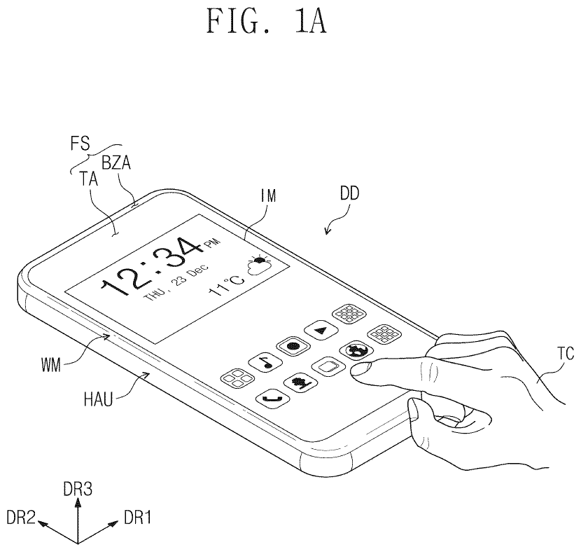

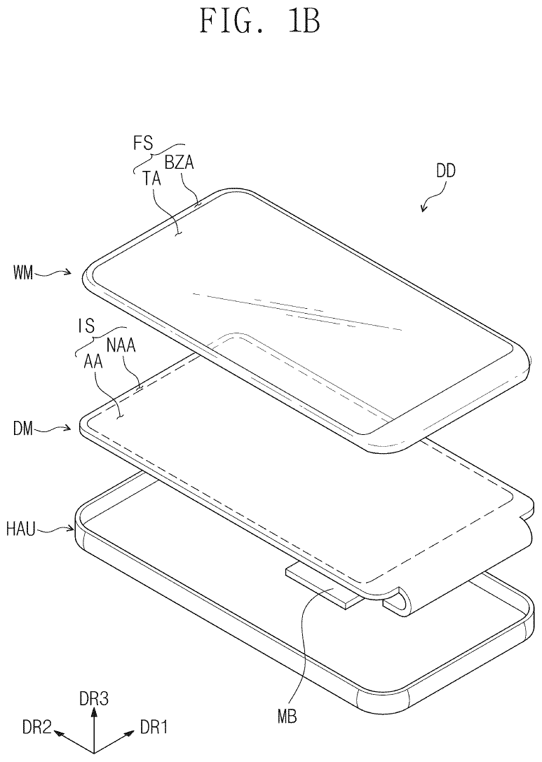

FIG. 1A is an assembled perspective view of a display device according to one or more embodiments of the present disclosure. FIG. 1B is an exploded perspective view of a display device according to one or more embodiments of the present disclosure. The present disclosure will be described with reference to FIG. 1A and FIG. 1B.

A display device DD may be activated in response to an electrical signal. The display device DD may display an image IM, and may sense an external input TC. The display device DD may include various embodiments. For example, the display device DD may include a tablet, a laptop computer, a computer, a smart television, etc. A smartphone is illustrated as an example of the display device DD.

The display device DD may display the image IM in a third direction DR3 on a display surface FS, which is parallel to each of a first direction DR1 and a second direction DR2. The display surface FS on which the image IM is displayed may correspond to a front surface of the display device DD, and may correspond to a front surface FS of a window WM. Hereinafter, the same reference symbol will be used for a display surface and a front surface of the display device DD and a front surface of the window WM. The image IM may include a still image as well as a dynamic image. A clock and a plurality of icons are illustrated as the image IM in FIG. 1A.

A front surface (or an upper surface) and a rear surface (or a lower surface) of each member are defined with respect to a direction in which the image IM is displayed. The front surface and the rear surface may be opposite each other in the third direction DR3, and a normal direction of each of the front surface and the rear surface may be parallel to the third direction DR3. A distance between the front surface and the rear surface in the third direction DR3 may correspond to a thickness of a display panel DP in the third direction DR3. Meanwhile, directions indicated by the first to third directions DR1, DR2, and DR3 may be relative concepts, and may thus be changed into other directions.

The display device DD according to one or more embodiments of the present disclosure may sense a user's input TC applied from the outside. The user's input TC includes various forms of external inputs, such as a body part of a user, light, heat, or pressure. A hand of a user applied to the front surface is illustrated as the user's input TC. However, this is illustrated as an example, and the user's input TC may be provided in various forms as described above, and in addition, the display device DD may also sense the user's input TC applied to a side surface or a rear surface of the display device DD depending on a structure of the display device DD, but one or more embodiments of the present disclosure is not limited thereto.

As illustrated in FIG. 1A and FIG. 1B, the display device DD includes a

window WM, a display module DM, and an external case HAU. The window WM and the external case HAU are coupled to each other to form an exterior of the display device DD. The external case HAU, the display module DM, and the window WM may be sequentially stacked in the third direction DR3.

The window WM may include an insulating panel. For example, the window WM may be composed of glass, plastic, or a combination thereof.

As described above, the front surface FS of the window WM defines the front surface of the display device DD. A transmission region TA may be an optically transparent region. For example, the transmission region TA may have a visible light transmittance of about 90% or more.

A bezel region BZA may have a lower light transmittance than the transmission region TA. The bezel region BZA defines a shape of the transmission region TA. The bezel region BZA may be adjacent to the transmission region TA, and may surround the transmission region TA (e.g., in plan view).

The bezel region BZA may have a color (e.g., a predetermined color). The

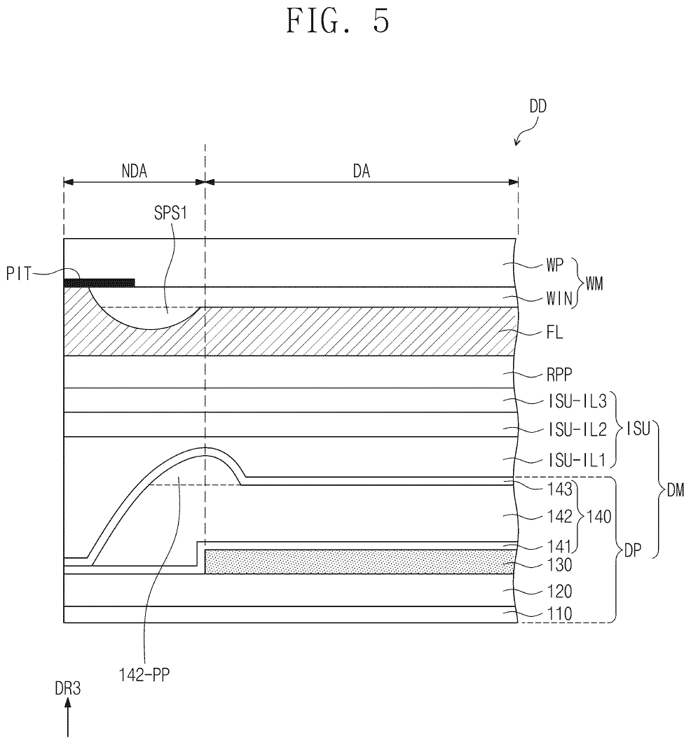

bezel region BZA may cover at least a portion of a peripheral region NAA of the display module DM so as to reduce or prevent visibility of the peripheral region NAA from the outside. Meanwhile, the bezel region BZA may be defined by a printed layer PIT (see FIG. 5), which will be described later.

The display module DM may display the image IM, and may sense the external input TC. The image IM may be displayed on a front surface IS of the display module DM. The front surface IS of the display module DM includes an active region AA and the peripheral region NAA. The active region AA may be activated in response to an electrical signal.

The active region AA may be a region where the image IM is displayed and where the external input TC is sensed at the same time. The transmission region TA overlaps at least the active region AA. For example, the transmission region TA overlaps the entire surface or at least a portion of the active region AA. Accordingly, through the transmission region TA, a user may view the image IM or may provide the external input TC. However, this is illustrated as an example, and in the active region AA, a region in which the image IM is displayed and a region in which the external input TC is sensed may be separated from each other, and one or more embodiments of the present disclosure is not limited thereto.

The peripheral region NAA may be covered by the bezel region BZA. At least a portion of the peripheral region NAA may be covered by the bezel region BZA. The peripheral region NAA is adjacent to the active region AA. The peripheral region NAA may surround the active region AA (e.g., in plan view). In the peripheral region NAA, a driving circuit, a driving wire, or the like for driving the active region AA may be located.

The display module DM may include a display panel and an input-sensing unit. The image IM may be substantially displayed on the display panel, and the external input TC may be substantially sensed by the input-sensing unit. The display module DM may include both the display panel and the input-sensing unit, and thus display the image IM and may sense the external input TC at the same time. Description thereof will be made later.

At least a portion of the display module DM may be bent. A portion, of the display module DM, to which a circuit board MB is connected may be bent toward a rear surface of the display module DM, and thus the circuit board MB may be assembled to overlap the rear surface of the display module DM.

Meanwhile, the display device DD may further include the circuit board MB connected to the display module DM. The circuit board MB is coupled to one side of the display module DM, and is thus physically and electrically connected to the display module DM. The circuit board MB may generate an electrical signal to be provided to the display module DM, or may receive a signal generated from the display module DM, and may calculate a result value including information on a sensed location or intensity of the external input TC.

The external case HAU is coupled to the window WM to define an exterior of the display device DD. The external case HAU provides an inner space (e.g., a predetermined inner space). The display module DM may be accommodated in the inner space.

The external case HAU may include a material having relatively high rigidity. For example, the external case HAU may include a plurality of frames and/or plates including glass, plastic, or metal, or may be composed of a combination thereof. The external case HAU may stably protect components of the display device DD, which are accommodated in the inner space, from an external impact.

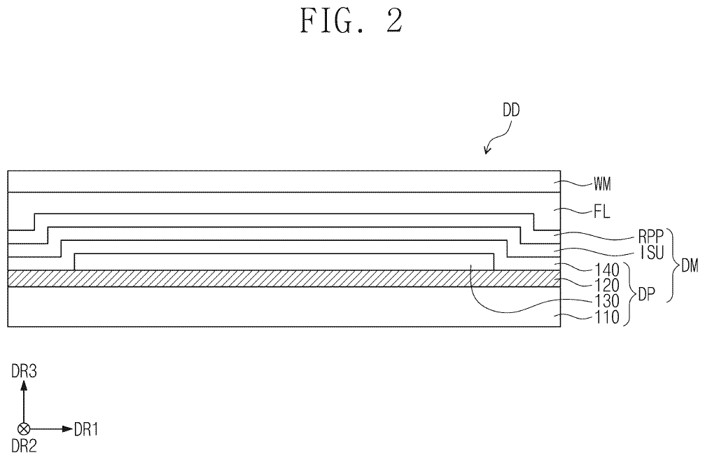

FIG. 2 is a cross-sectional view of a display device according to one or more embodiments of the present disclosure. Referring to FIG. 2, a display device DD may include a display panel DP, an input-sensing unit ISU, an anti-reflector RPP, and a window WM.

The display panel DP may be an emission-type display panel, such as an organic light-emitting display panel, an inorganic light-emitting display panel, a micro-LED display panel, or a nano-LED display panel. The display panel DP may include a base layer 110, a circuit layer 120, a light-emitting element layer 130, and an encapsulation layer 140.

The base layer 110 may provide a base surface on which the circuit layer 120 is located. The base layer 110 may be a rigid substrate or a flexible substrate, which is capable of bending, folding, rolling, etc. The base layer 110 may be a glass substrate, a metal substrate, a polymer substrate, or the like. However, one or more embodiments of the present disclosure is not limited thereto, and the base layer 110 may include an inorganic layer, an organic layer, or a composite layer.

The base layer 110 may have a multi-layered structure. For example, the base layer 110 may include a first synthetic resin layer, a multi-or single-layered inorganic layer, and a second synthetic resin layer located on the multi-or single-layered inorganic layer. Each of the first and second synthetic resin layers may include a polyimide-based resin, but one or more embodiments of the present disclosure is not limited thereto.

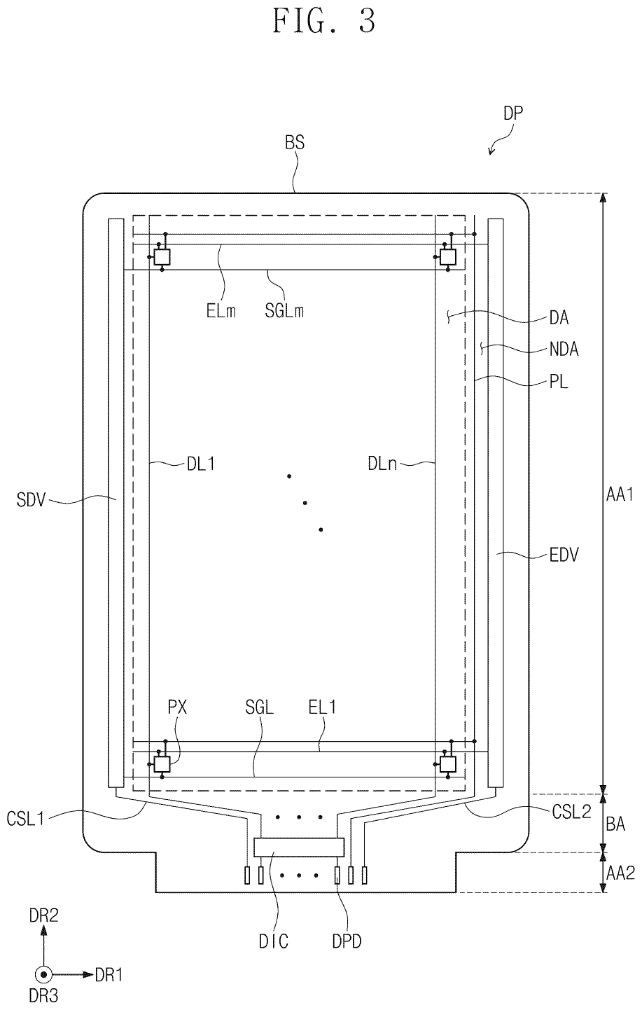

The circuit layer 120 may be located on the base layer 110. The circuit layer 120 may include an insulating layer, a semiconductor pattern, a conductive pattern, a signal line, etc. The circuit layer 120 includes a driving circuit for a pixel PX (see FIG. 3), which will be described later.

The light-emitting element layer 130 may be located on the circuit layer 120. The light-emitting element layer 130 may include a light-emitting element of a pixel PX (see FIG. 3), which will be described later. For example, the light-emitting element may include an organic light-emitting material, an inorganic light-emitting material, an organic-inorganic light-emitting material, a quantum dot, a quantum rod, a micro-LED, or a nano-LED.

The encapsulation layer 140 may be located on the light-emitting element layer 130. The encapsulation layer 140 may protect the light-emitting element layer 130 from foreign substances, such as moisture, oxygen, and/or dust particles. The encapsulation layer 140 may include at least one inorganic layer. The encapsulation layer 140 may include a stacked structure of an inorganic layer/an organic layer/an inorganic layer.

The input-sensing unit ISU may be located on the display panel DP. The input-sensing unit ISU may sense an external input applied from the outside. The external input may be a user's input. The user's input may include various forms of external inputs, such as a body part of a user, light, heat, a pen, or pressure.

The input-sensing unit ISU may be formed on the display panel DP through a continuous process. In this case, the input-sensing unit ISU may be directly located on the display panel DP. As used herein, the wording, “a component B is directly located on a component A” may mean that no intervening element is located therebetween (e.g., there may be no adhesive layer between the input-sensing unit ISU and the display panel DP).

The anti-reflector RPP may be located on the input-sensing unit ISU. The anti-reflector RPP may reduce a reflectance for external light. The anti-reflector RPP may be directly located on the input-sensing unit ISU through a continuous process.

The anti-reflector RPP reduces a reflectance for external light incident from above the window WM. According to one or more embodiments of the present disclosure, the anti-reflector RPP may include a retarder and a polarizer. The retarder may be a film-type retarder or a liquid crystal coating-type retarder, and may include a λ/2 retarder and/or a λ/4 retarder. The polarizer may also be a film-type polarizer or a liquid crystal coating-type polarizer. The film type may include a stretchable synthetic resin film, and the liquid crystal coating type may include liquid crystals arranged in an arrangement (e.g., a predetermined arrangement). The retarder and polarizer may further include a protective film. The retarder and polarizer themselves or the protective film may be defined as a base layer of the anti-reflector RPP.

According to one or more embodiments of the present disclosure, the anti-reflector RPP may include color filters. The color filters have an arrangement (e.g., a predetermined arrangement). An arrangement of the color filters may be determined in consideration of colors of light emitted from pixels that are included in the display panel DP. The anti-reflector RPP may further include a black matrix adjacent to the color filters. The anti-reflector RPP including the color filters may be directly located on the display panel DP.

The window WM is located on the anti-reflector RPP. The window WM and the anti-reflector RPP may be spaced apart from each other with an intermediate layer FL therebetween. The window WM and the anti-reflector RPP may be coupled to each other by the intermediate layer FL. The intermediate layer FL may be an adhesive layer. The adhesive layer may be a pressure sensitive adhesive (PSA) film or an optically clear adhesive (OCA) member. The intermediate layer FL may include a polymer resin.

The window WM includes at least one base substrate. The base substrate may be a glass substrate or a synthetic resin film. The window WM may have a multi-layered structure. The window WM may include a thin-film glass substrate and a synthetic resin film located on the thin-film glass substrate. The thin-film glass substrate and the synthetic resin film may be coupled to each other by an adhesive layer, and the adhesive layer and the synthetic resin film may be separated from the thin-film glass substrate for the purpose of replacement thereof.

In one or more embodiments of the present disclosure, the intermediate layer FL may be omitted, and the window WM may be directly located on the anti-reflector RPP. An organic material, an inorganic material, or a ceramic material may be applied onto the anti-reflector RPP.

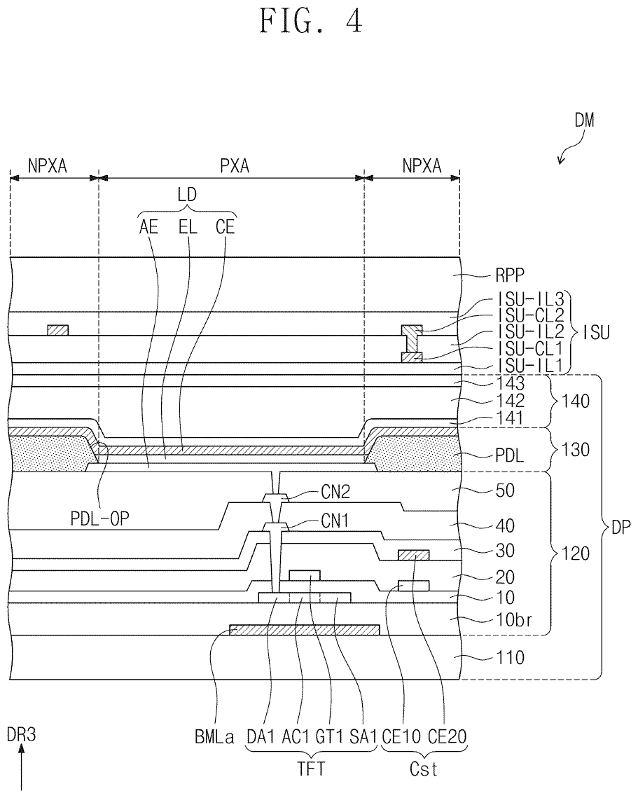

FIG. 3 is a plan view of a display panel according to one or more embodiments of the present disclosure. FIG. 4 is a cross-sectional view of a display module according to one or more embodiments of the present disclosure. A display panel DP and a display module DM according to one or more embodiments of the present disclosure will be described below with reference to FIG. 3 and FIG. 4.

Referring to FIG. 3 and FIG. 4 together, a display module DM may include a display panel DP and an input-sensing unit ISU. The display panel DP generates the image IM. FIG. 3 illustrates some of components of the display panel DP in a plan view.

FIG. 3 illustrates some of components of the display panel DP in a block shape for ease of description. Referring to FIG. 3, the display panel DP may include a base layer 110, a scan-driving circuit SDV, a light-emission-driving circuit EDV, a driving chip DIC, a plurality of panel signal lines SGL to SGLm, DL1 to DLn, EL1 to ELm, CSL1, CSL2, and PL, a plurality of pixels PX, and a plurality of display pads DPD.

The base layer 110 includes a first base region AA1, a second base region AA2, and a bending region BA, which are distinguished from each other in a second direction DR2. The second base region AA2 and the bending region BA may be a portion of a non-display region NDA. The bending region BA is located between the first base region AA1 and the second base region AA2.

The first base region AA1 may include the front surface IS in FIG. 1B. The second base region AA2 is spaced apart from the first base region AA1 with the bending region BA therebetween. Each of the second base region AA2 and the bending region BA may have a smaller width in a first direction DR1 than the first base region AA1. That is, each of the bending region BA and the second base region AA2 may have a smaller length in the first direction DR1 than the first base region AA1.

A region having a smaller length in a bending axis direction may be more easily bent. However, this is illustrated as an example, and each of the second base region AA2 and the bending region BA may have the same width in the first direction DR1 as the first base region AA1, and one or more embodiments of the present disclosure is not limited thereto.

The bending region BA is bent with respect to a bending axis extending in

the first direction DR1. When the bending region BA is not bent, the second base region AA2 may be oriented in the same direction as the first base region AA1, and when the bending region BA is bent, the second base region AA2 may be oriented in a direction opposite to the first base region AA1 (e.g., the second base region AA2 may be below the first base region AA1).

The circuit board MB (see FIG. 1B) described above is physically connected to the second base region AA2. As the bending region BA is bent, the circuit board MB is positioned on a rear surface of a display panel. Accordingly, a region defining the front surface IS becomes the first base region AA1, and the second base region AA2 and the bending region BA are invisible through the front surface IS. Thus, a bezel area of a display device may be reduced.

Each of the pixels PX includes a light-emitting element and a thin-film transistor connected to the light-emitting element. A shape of the display panel DP illustrated in FIG. 3 is substantially the same as a planar shape of the base layer described above. A display region DP-DA and a non-display region DP-NDA may be distinguished from each other according to whether the light-emitting element is located or not.

FIG. 3 illustrates that the pixels PX are located in a display region DA. The display region DA may be a region in which the image IM is displayed. Meanwhile, this is illustrated as an example, and some of components of each pixel PX may include a thin-film transistor located in a non-display region NDA, and one or more embodiments of the present disclosure is not limited thereto.

The scan-driving circuit SDV, the driving chip DIC, and the light-emission-driving circuit EDV may be located in the non-display region NDA. The driving chip DIC may include a data-driving circuit.

The panel signal lines SGL to SGLm, DL1 to DLn, EL1 to Elm, CSL1, CSL2, and PL may include a plurality of scan lines SGL to SGLm, a plurality of data lines DL1 to DLn, a plurality of light emission lines EL1 to ELm, first and second control lines CSL1 and CSL2, and a power line PL. Among the panel signal lines SGL to SGLm, DL1 to DLn, EL1 to ELm, CSL1, CSL2, and PL, the data lines DL1 to DLn, the first and second control lines CSL1 and CSL2, and the power line PL may be respectively connected to the plurality of display pads DPD. Here, m and n are natural numbers. The pixels PX may be connected to the scan lines SGL to SGLm, the data lines DL1 to

DLn, and the light emission lines EL1 to ELm.

The scan lines SGL to SGLm may extend in the first direction DR1, and may be connected to the scan-driving circuit SDV. The data lines DL1 to DLn may extend in the second direction DR2, and may be connected to the driving chip DIC via the bending region BA. The light emission lines EL1 to ELm may extend in the first direction DR1, and may be connected to the light-emission-driving circuit EDV.

The power line PL may have a portion extending in the second direction DR2 and a portion extending in the first direction DR1. The portion extending in the first direction and the portion extending in the second direction may be located on different layers. The portion of the power line PL extending in the second direction DR2 may extend to the second base region AA2 via the bending region BA. The power line PL may provide a first voltage to the pixels PX.

The first control line CSL1 may be connected to the scan-driving circuit SDV, and may extend toward a lower end of the second base region AA2 via the bending region BA. The second control line CSL2 may be connected to the light-emission-driving circuit EDV, and may extend toward the lower end of the second base region AA2 via the bending region BA.

In a plan view, the display pads DPD may be located adjacent to the lower end of the second base region AA2. The driving chip DIC, the power line PL, the first control line CSL1, and the second control line CSL2 may be connected to the display pads DPD. The circuit board MB may be electrically connected to the display pads DPD through an anisotropic conductive adhesive layer.

FIG. 4 illustrates a cross section corresponding to one pixel region PXA, and a non-pixel region NPXA around the pixel region PXA (e.g., in plan view). FIG. 4 mainly illustrates a cross section of a light-emitting element LD and a transistor TFT connected thereto, which are included in one pixel PX. The transistor may be one of a plurality of transistors included in a driving circuit for a pixel PX. The transistor TFT is described as a silicon transistor, but may be a metal oxide transistor.

A base layer 110 may be a flexible substrate capable of bending, folding, rolling, etc. The base layer 110 may be a glass substrate, a metal substrate, a polymer substrate, or the like. However, one or more embodiments of the present disclosure is not limited thereto, and the base layer 110 may be an inorganic layer, an organic layer, or a composite layer. The base layer 110 has the substantially same shape as a display panel DP.

The base layer 110 may have a multi-layered structure. For example, the base layer 110 may include a first synthetic resin layer, a second synthetic resin layer, and inorganic layers located therebetween. Each of the first and second synthetic resin layers may include a polyimide-based resin, but one or more embodiments of the present disclosure is not limited thereto.

A buffer layer 10br may be located on the base layer 110. The buffer layer 10br may reduce or prevent the diffusion of metal atoms or impurities from the base layer 110 to a semiconductor pattern thereabove. The semiconductor pattern includes an active region AC1 of the transistor TFT.

A shielding pattern BMLa may be located below the transistor TFT. The shielding pattern BMLa may block external light from reaching the transistor TFT. The shielding pattern BMLa may be located between the base layer 110 and the buffer layer 10br. In one or more embodiments of the present disclosure, an inorganic barrier layer may be further located between the shielding pattern BMLa and the buffer layer 10br. The shielding pattern BMLa may be connected to an electrode or a wire, and may receive a constant voltage or a signal therefrom.

The semiconductor pattern may be located on the buffer layer 10br. The

semiconductor pattern may include a silicon semiconductor. For example, the silicon semiconductor may include amorphous silicon, polycrystalline silicon, etc. For example, the semiconductor pattern may include low-temperature polysilicon.

The semiconductor pattern may include a first region having high conductivity, and a second region having low conductivity. The first region may be doped with an N-type dopant or a P-type dopant. A P-type transistor may include a doped region doped with a P-type dopant, and an N-type transistor may include a doped region doped with an N-type dopant. The second region may be an undoped region or a region doped with a lower concentration than the first region.

The first region may have higher conductivity than the second region, and the first region may substantially serve as an electrode or a signal line. The second region may substantially correspond to an active region (or a channel) of a transistor. In other words, a portion of the semiconductor pattern may be an active region of a transistor, and another portion of the semiconductor pattern may be a source or a drain of a transistor, and still another portion of the semiconductor pattern may be a connecting electrode or a connecting signal line.

A source region SA1 (or a source), an active region AC1 (or a channel), and a drain region DA1 (or a drain) of the transistor TFT may be formed from the semiconductor pattern. On a cross section, the source region SA1 and drain region DA1 may respectively extend in directions opposite to each other from the active region AC1.

A first insulating layer 10 may be located on the buffer layer 10br. The first insulating layer 10 may overlap the plurality of pixels PX (see FIG. 1) in common, and may cover the semiconductor pattern. The first insulating layer 10 may include an inorganic and/or organic layer, and may have a single-or multi-layered structure. The inorganic layer may contain at least one of aluminum oxide, titanium oxide, silicon oxide, silicon nitride, silicon oxynitride, zirconium oxide, or hafnium oxide. The first insulating layer 10 may be a single-layered silicon oxide layer. Not only the first insulating layer 10, but also an insulating layer of a circuit layer 120, which will be described later, may be an inorganic and/or organic layer, and may have a single-or multi-layered structure. The inorganic layer may contain at least one of the materials described above, but one or more embodiments of the present disclosure is not limited thereto.

A gate GT1 of the transistor TFT is located on the first insulating layer 10. The gate GT1 may be a portion of a metal pattern. The gate GT1 overlaps the active region AC1. The gate GT1 may function as a mask in a doping process of the semiconductor pattern. The gate GT1 may contain titanium (Ti), silver (Ag), silver-containing alloy, molybdenum (Mo), molybdenum-containing alloy, aluminum (Al), aluminum-containing alloy, aluminum nitride (AlN), tungsten (W), tungsten nitride (WN), copper (Cu), indium tin oxide (ITO), indium zinc oxide (IZO), etc., but one or more embodiments of the present disclosure is not limited thereto.

A second insulating layer 20 may be located on the first insulating layer 10, may cover the gate GT1. A third insulating layer 30 may be located on the second insulating layer 20. A second electrode CE20 of a storage capacitor Cst may be located between the second insulating layer 20 and the third insulating layer 30. In addition, a first electrode CE10 of the storage capacitor Cst may be located between the first insulating layer 10 and the second insulating layer 20.

A first connecting electrode CN1 may be located on the third insulating layer 30. The first connecting electrode CN1 may be connected to the drain region DA1 of the transistor TFT through a contact hole that penetrates the first to third insulating layers 10, 20, and 30.

A fourth insulating layer 40 may be located on the third insulating layer 30. A second connecting electrode CN2 may be located on the fourth insulating layer 40. The second connecting electrode CN2 may be connected to the first connecting electrode CN1 through a contact hole that penetrates the fourth insulating layer 40. A fifth insulating layer 50 may be located on the fourth insulating layer 40, and may cover the second connecting electrode CN2. A stacked structure having the first insulating layer 10 to the fifth insulating layer 50 is illustrated as an example, and an additional conductive layer and an additional insulating layer other than the first insulating layer 10 to the fifth insulating layer 50 may be further located.

Each of the fourth insulating layer 40 and the fifth insulating layer 50 may be an organic layer. For example, the organic layer may contain benzocyclobutene (BCB), polyimide, hexamethyldisiloxane (HMDSO), a general-purpose polymer, such as polymethylmethacrylate (PMMA) or polystyrene (PS), a polymer derivative having a phenol-based group, an acrylate-based polymer, an imide-based polymer, an arylether-based polymer, an amide-based polymer, a fluorine-based polymer, a p-xylene-based polymer, a vinyl alcohol-based polymer, a blend thereof, etc.

The light-emitting element LD may include a first electrode AE (or a pixel electrode), a light-emitting layer EL, and a second electrode CE (or a common electrode). The first electrode AE may be located on the fifth insulating layer 50. The first electrode AE may be a (semi-) light-transmissive electrode or a reflective electrode. The first electrode AE may include a reflective layer formed of Ag, Mg, Cu, Al, Pt, Pd, Au, Ni, Nd, Ir, Cr, Li, Ca, LiF/Ca, LiF/AI, Mo, Ti, Yb, W, a compound thereof, or a mixture thereof (e.g., AgMg, AgYb, or MgYb), and a transparent or translucent electrode layer that is formed on the reflective layer. The transparent or translucent electrode layer may include at least one selected from the group consisting of indium tin oxide (ITO), indium zinc oxide (IZO), indium gallium zinc oxide (IGZO), zinc oxide (ZnO), indium oxide (In₂O₃), or aluminum-doped zinc oxide (AZO). For example, the first electrode AE may include a stacked structure of ITO/Ag/ITO.

A pixel-defining film PDL may be located on the fifth insulating layer 50. According to one or more embodiments, the pixel-defining film PDL may have a light-absorbing property, and for example, the pixel-defining film PDL may have a black color. The pixel-defining film PDL may include a black coloring agent. The black coloring agent may include a black dye or a black pigment. The black coloring agent may include carbon black, metal, such as chromium, or oxides thereof. The pixel-defining film PDL may correspond to a light-shielding pattern that has a light-shielding property.

The pixel-defining film PDL may cover a portion of the first electrode AE (e.g., an anode). For example, an opening PDL-OP exposing a portion of the first electrode AE may be defined in the pixel-defining film PDL. The opening PDL-OP of the pixel-defining film PDL may define a pixel region PXA.

The pixel-defining film PDL may increase a distance between an edge of the first electrode AE and the second electrode CE (e.g., a cathode). Accordingly, the pixel-defining film PDL may reduce or prevent the likelihood of an arc occurring at the edge of the first electrode AE.

In one or more embodiments, a hole control layer may be located between the first electrode AE and the light-emitting layer EL. The hole control layer may include a hole transport layer, and may further include a hole injection layer. An electron control layer may be located between the light-emitting layer EL and the second electrode CE. The electron control layer may include an electron transport layer, and may further include an electron injection layer.

An encapsulation layer 140 may be located on a light-emitting element layer 130. The encapsulation layer 140 may include a first inorganic encapsulation layer 141, an organic encapsulation layer 142, and a second inorganic encapsulation layer 143, which are stacked in sequence, but layers constituting the encapsulation layer 140 are not limited thereto.

The inorganic encapsulation layers 141 and 143 may protect the light-emitting element layer 130 from moisture and oxygen, and the organic encapsulation layer 142 may protect the light-emitting element layer 130 from foreign substances, such as dust particles. The inorganic encapsulation layers 141 and 143 may include a silicon nitride layer, a silicon oxynitride layer, a silicon oxide layer, a titanium oxide layer, or an aluminum oxide layer. The organic encapsulation layer 142 may include an acrylate-based organic layer, but one or more embodiments of the present disclosure is not limited thereto.

An input-sensing unit ISU may be located on a display panel DP. The input-sensing unit ISU may include a first sensing insulating layer ISU-IL1, a first conductive pattern layer ISU-CL1, a second sensing insulating layer ISU-IL2, a second conductive pattern layer ISU-CL2, and a third sensing insulating layer ISU-IL3. The first sensing insulating layer ISU-IL1 may be directly located on the encapsulation layer 140.

In one or more embodiments of the present disclosure, the first sensing insulating layer ISU-IL1 and/or the third sensing insulating layer ISU-IL3 may be omitted. When the first sensing insulating layer ISU-IL1 is omitted, the first conductive pattern layer ISU-CL1 may be located on an uppermost insulating layer of the encapsulation layer 140. The third sensing insulating layer ISU-IL3 may be replaced with an adhesive layer or with an insulating layer of an anti-reflector RPP that is located on the input-sensing unit ISU.

The first conductive pattern layer ISU-CL1 may include first conductive patterns, and the second conductive pattern layer ISU-CL2 may include second conductive patterns. A first conductive pattern layer ISU-CL1 is located on the first sensing insulating layer ISU-IL1. A second conductive pattern layer ISU-CL2 is located on the second sensing insulating layer ISU-IL2. Hereinafter, the first conductive pattern layer ISU-CL1 and the first conductive patterns are denoted as the same reference numerals and symbols, and the second conductive pattern layer ISU-CL2 and the second conductive patterns are denoted as the same reference numerals and symbols. Meanwhile, the first conductive patterns ISU-CL1 and the second conductive patterns ISU-CL2 may respectively correspond to a sensing electrode and a signal line, which will be described later.

Each of the first conductive patterns ISU-CL1 and the second conductive patterns ISU-CL2 may have a single-layered structure or a multi-layered structure in which layers are stacked along a third direction DR3. A conductive pattern having a multi-layered structure may include at least two among transparent conductive layers and metal layers. The conductive pattern having a multi-layered structure may include metal layers containing different metals. The transparent conductive layers may each contain indium tin oxide (ITO), indium zinc oxide (IZO), zinc oxide (ZnO), indium tin zinc oxide (ITZO), PEDOT, a metal nanowire, or graphene. The metal layers may each contain molybdenum, silver, titanium, copper, aluminum, or an alloy thereof.

A thickness of each of the first conductive patterns ISU-CL1 and the second conductive patterns ISU-CL2 may be about 0.1 micrometer to about 1 micrometer. When the thickness of each of the first conductive patterns ISU-CL1 and the second conductive patterns ISU-CL2 is less than about 0.1 micrometer, wiring resistance may increase, and input-sensing performance of the input-sensing unit ISU may be reduced. When the thickness of each of the first conductive patterns ISU-CL1 and the second conductive patterns ISU-CL2 is more than about 1 micrometer, a thickness of the input-sensing unit ISU may excessively increase, and thus a total thickness of the display device DD (see FIG. 1A) may increase, and a folding property may be reduced.

Each of the first sensing insulating layer ISU-IL1 to the third sensing insulating layer ISU-IL3 may include an inorganic layer or an organic layer. The first sensing insulating layer ISU-IL1 to the third sensing insulating layer ISU-IL3 may include an inorganic layer. The inorganic layer may contain silicon oxide, silicon nitride, or silicon oxynitride.

In one or more embodiments of the present disclosure, at least one among the first sensing insulating layer ISU-IL1 to the third sensing insulating layer ISU-IL3 may be an organic layer. For example, the third sensing insulating layer ISU-IL3 may include an organic layer. The organic layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

The anti-reflector RPP may be located on the input-sensing unit ISU. The anti-reflector RPP may reduce a reflectance for external light. The anti-reflector RPP may be directly located on the input-sensing unit ISU through a continuous process.

The anti-reflector RPP may reduce a reflectance for external light incident from above the window WM. According to one or more embodiments of the present disclosure, the anti-reflector RPP may include a retarder and a polarizer. The retarder may be a film-type retarder or a liquid crystal coating-type retarder, and may include a λ/2 retarder and/or a λ/4 retarder. The polarizer may also be a film-type polarizer or a liquid crystal coating-type polarizer. The film-type may include a stretchable synthetic resin film, and the liquid crystal coating-type may include liquid crystals arranged in an arrangement (e.g., a predetermined arrangement). The retarder and the polarizer may further include a protective film. The retarder and the polarizer themselves or the protective film may be defined as a base layer of the anti-reflector RPP.

According to one or more embodiments of the present disclosure, the anti-reflector RPP may include color filters. The color filters have an arrangement (e.g., a predetermined arrangement). An arrangement of the color filters may be determined in consideration of colors of light emitted from pixels that are included in the display panel DP. The anti-reflector RPP may further include a black matrix adjacent to the color filters. The anti-reflector RPP including the color filters may be directly located on the display panel DP. When the anti-reflector RPP includes the color filters, the anti-reflector RPP may further include a light-shielding pattern overlapping the non-pixel region NPXA. When the anti-reflector RPP includes the color filters, the anti-reflector RPP may further include a planarization layer covering the color filters.

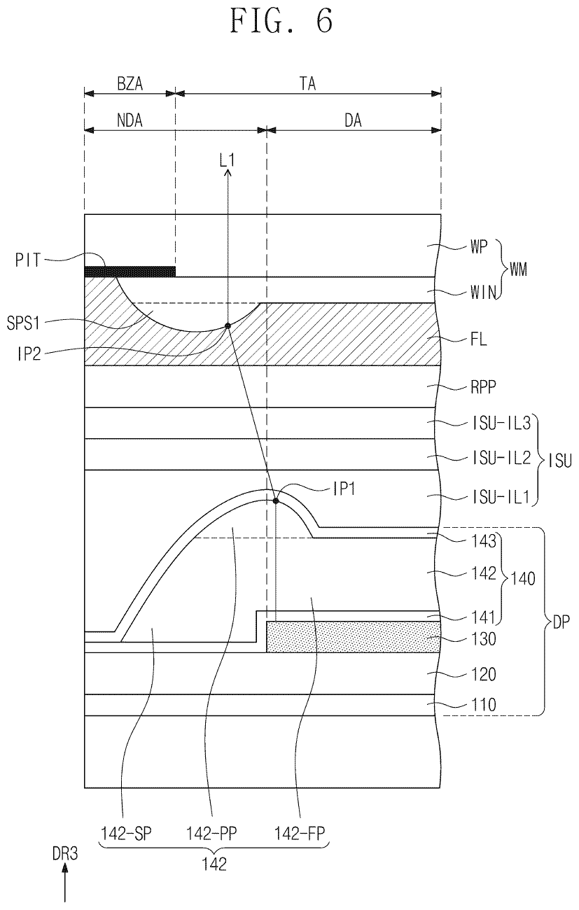

FIG. 5 is a cross-sectional view of a portion of a display device according to one or more embodiments of the present disclosure. FIG. 6 is an enlarged cross-sectional view of a portion of a display device according to one or more embodiments of the present disclosure. FIG. 5 and FIG. 6 illustrates a cross section corresponding to a non-display region NDA and a portion of a display region DA adjacent thereto in a display panel DP.

Referring to FIG. 5, the display panel DP may include a base layer 110, a circuit layer 120, a light-emitting element layer 130, and an encapsulation layer 140. The encapsulation layer 140 includes at least an organic encapsulation layer 142. The encapsulation layer 140 may include a first inorganic encapsulation layer 141, the organic encapsulation layer 142, and a second inorganic encapsulation layer 143, which are stacked in sequence.

The organic encapsulation layer 142 may have a larger thickness than the inorganic encapsulation layers 141 and 143, and provide a flat upper surface by covering the light-emitting element layer 130. The organic encapsulation layer 142 overlaps the display region DA and at least a portion of the non-display region NDA. The organic encapsulation layer 142 may overlap a portion of the non-display region NDA and may not overlap the remaining portion of the non-display region NDA, and the first inorganic encapsulation layer 141 and the second inorganic encapsulation layer 143 may be in contact with each other in a region in which the organic encapsulation layer 142 is not located.

The organic encapsulation layer 142 includes a protrusion 142-PP at least a portion of which overlaps the display region DA. The protrusion 142-PP may overlap a boundary between the display region DA and the non-display region NDA. A portion of the protrusion 142-PP may overlap the display region DA, and the remaining portion of the protrusion 142-PP may overlap the non-display region NDA. The protrusion 142-PP may be formed at the boundary between the display region DA and the non-display region NDA due to a step caused by components that are included in the light-emitting element layer 130.

The protrusion 142-PP has a shape protruding along a third direction DR3 that is a thickness direction. The protrusion 142-PP may have a shape protruding to be adjacent to an input-sensing unit ISU. The protrusion 142-PP may have a convex shape having a rounded upper surface.

The organic encapsulation layer 142 may further include a flat portion 142-FP overlapping the display region DA, and an inclined portion 142-SP overlapping the non-display region NDA. The inclined portion 142-SP may be a portion more adjacent to an end of a display device DD than the flat portion 142-FP and having a slope inclined at an angle (e.g., a predetermined angle) with respect to a plane parallel to an upper surface of the base layer 110. The flat portion 142-FP may be a portion having a flat surface parallel to the upper surface of the base layer 110. The protrusion 142-PP may be located between the flat portion 142-FP and the inclined portion 142-SP. The protrusion 142-PP may be a portion protruding by a height (e.g., a predetermined height) from an upper surface of the flat portion 142-FP.

A display device DD may include the input-sensing unit ISU, an anti-reflector RPP, an intermediate layer FL, and a window WM, which are located on the display panel DP in sequence.

The input-sensing unit ISU may include at least one sensing insulating layer. The input-sensing unit ISU may include a first sensing insulating layer ISU-IL1, a second sensing insulating layer ISU-IL2, and a third sensing insulating layer ISU-IL3, which are stacked in sequence. The first sensing insulating layer ISU-IL1 may be directly located on the encapsulation layer 140. In one or more embodiments of the present disclosure, the first sensing insulating layer ISU-IL1 and/or the third sensing insulating layer ISU-IL3 may be omitted. In one or more embodiments, the input-sensing unit ISU may further include the first conductive pattern layer ISU-CL1 (see FIG. 4) located on the first sensing insulating layer ISU-IL1, and the second conductive pattern layer ISU-CL2 (see FIG. 4) located on the second sensing insulating layer ISU-IL2.

The window WM provides an external surface of the display device DD. The window WM includes a base substrate WIN. The base substrate WIN may have an optically transparent property. The base substrate WIN may include a glass substrate or a synthetic resin film. For example, the base substrate WIN may include a thin-film glass substrate.

The window WM may include the base substrate WIN, a window protective layer WP, and a printed layer PIT (or a black matrix layer).

The window protective layer WP may be located on the base substrate WIN. In one or more embodiments, the window protective layer WP may be attached onto the base substrate WIN through an adhesive layer. The window protective layer WP may include a flexible plastic material, such as polyimide or polyethylene terephthalate.

The printed layer PIT may be located on a lower surface of the window protective layer WP. The printed layer PIT may be a black matrix layer. The printed layer PIT may have a black color, but a color of the printed layer PIT is not limited thereto. The printed layer PIT may be adjacent to an edge of the window protective layer WP. The printed layer PIT may overlap the non-display region NDA. A stacked structure of the window WM is not necessarily limited to the structure described above, and the window WM may further include a hard coating layer located on the window protective layer WP.

The window WM may be divided into a transmission region TA and a bezel region BZA. The transmission region TA may be an optically transparent region. For example, the transmission region TA may have a visible light transmittance of about 90% or more. The bezel region BZA may have a lower light transmittance than the transmission region TA. The bezel region BZA defines a shape of the transmission region TA. The bezel region BZA may be adjacent to the transmission region TA, and may surround the transmission region TA.

The bezel region BZA may have a color (e.g., a predetermined color). The bezel region BZA may be defined by the printed layer PIT. In the display device DD according to one or more embodiments, a width of the bezel region BZA may be smaller than a width of the non-display region NDA. That is, only a portion of the non-display region NDA may be covered by the printed layer PIT, and the remaining portion of the non-display region NDA may not overlap the printed layer PIT.

The display device DD according to one or more embodiments includes an optical structure overlapping the protrusion 142-PP. The optical structure may overlap the protrusion 142-PP on a plane, and thus may change a path of light refracted or scattered by the protrusion 142-PP, or may block at least portion of the refracted or scattered light. The display device DD according to one or more embodiments may reduce the amount of the refracted or scattered light due to having the optical structure, so that the likelihood of a stain or the like may be reduced or prevented from occurring in the display region DA adjacent to the non-display region NDA, thereby improving a visibility of the display device DD. Although the display device DD according to one or more embodiments includes the printed layer PIT having a small width that exposes a portion of the non-display region NDA, the display device DD may reduce the amount of the refracted or scattered light due to having the optical structure. The optical structure may be included in the input-sensing unit ISU or the window WM, which is located on the display panel DP. The optical structure may overlap the non-display region NDA.

As illustrated in FIG. 5 and FIG. 6, the window WM of the display device DD may include a first optical structure SPS1 protruding from the base substrate WIN. The first optical structure SPS1 may protrude downwardly. The first optical structure SPS1 may protrude from the base substrate WIN to be adjacent to the intermediate layer FL. The first optical structure SPS1 may have a convex shape having a rounded lower surface. The first optical structure SPS1 may be located in the non-display region NDA, and at least a portion of the first optical structure SPS1 may overlap the protrusion 142-PP of the organic encapsulation layer 142.

The first optical structure SPS1 and the base substrate WIN may be provided as one piece. The first optical structure SPS1 and the base substrate WIN may include the same material, and may be formed through the same process. The base substrate WIN and the first optical structure SPS1 may originate from the same mother substrate. In one or more embodiments, when a slimming process is performed on the mother substrate that is a glass substrate, the base substrate WIN and the first optical structure SPS1 may be formed by adjusting a thickness of a portion that corresponds to the first optical structure SPS1.

The first optical structure SPS1 may compensate for the path of light refracted or scattered by the protrusion 142-PP of the organic encapsulation layer 142, and thus may improve the visibility of the display device DD.

As illustrated in FIG. 6, light L1 generated in the display region DA that is adjacent to the non-display region NDA, and travelling along a third direction DR3 at an early stage, may be refracted at a first point IP1 in an interface between the protrusion 142-PP and the input-sensing unit ISU.

Meanwhile, the organic encapsulation layer 142 including the protrusion 142-PP may be different in refractive index from the input-sensing unit ISU. In a visible light wavelength range of about 380 nm to about 780 nm, the organic encapsulation layer 142 may have a refractive index that is different from a refractive index of at least one among the plurality of sensing insulating layers ISU-IL1, ISU-IL2, or ISU-IL3 (see FIG. 5) included in the input-sensing unit ISU. In the visible light wavelength range, the refractive index of at least one among the plurality of sensing insulating layers ISU-IL1, ISU-IL2, or ISU-IL3 may be larger than the refractive index of the organic encapsulation layer 142.

The light L1 refracted at the first point IP1 may be refracted again at an interface between the intermediate layer FL and the window WM. The light L1 may be refracted again by the first optical structure SPS1 protruding toward/from a lower side of the base substrate WIN of the window WM, and thus a path of light may be adjusted so that the light again travels in the third direction DR3 that is a frontal direction. The light L1 may be re-refracted at a second point IP2 in an interface between the intermediate layer FL and the first optical structure SPS1, and thus may travel in the third direction DR3. In the display device DD according to one or more embodiments, even if the light L1 emitted in the frontal direction is refracted at the first point IP1, and thus a path of light is changed, the path of the light L1 may be changed again into the third direction DR3 by the first optical structure SPS1. Therefore, the display device DD may reduce the amount of light refracted or scattered, thereby reducing or preventing the likelihood of a stain or the like occurring in the display region DA adjacent to the non-display region NDA.

Meanwhile, the base substrate WIN and the first optical structure SPS1, which are provided as one piece, may be different from the intermediate layer FL with respect to refractive indices. In a visible light wavelength range of about 380 nm to about 780 nm, the base substrate WIN and the first optical structure SPS1 may have a refractive index that is different from a refractive index of the intermediate layer FL. In the visible light wavelength, the refractive index of the intermediate layer FL may be larger than the refractive index of each of the base substrate WIN and the first optical structure SPS1.

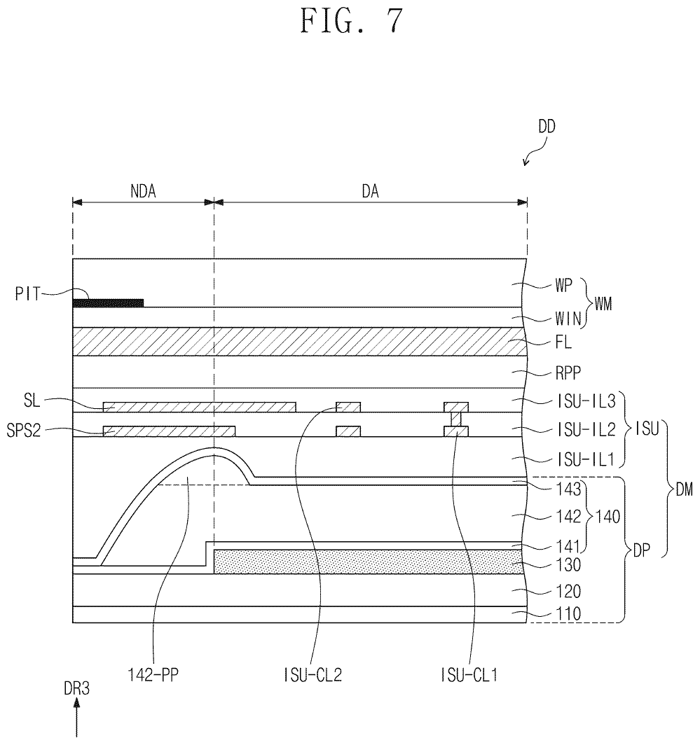

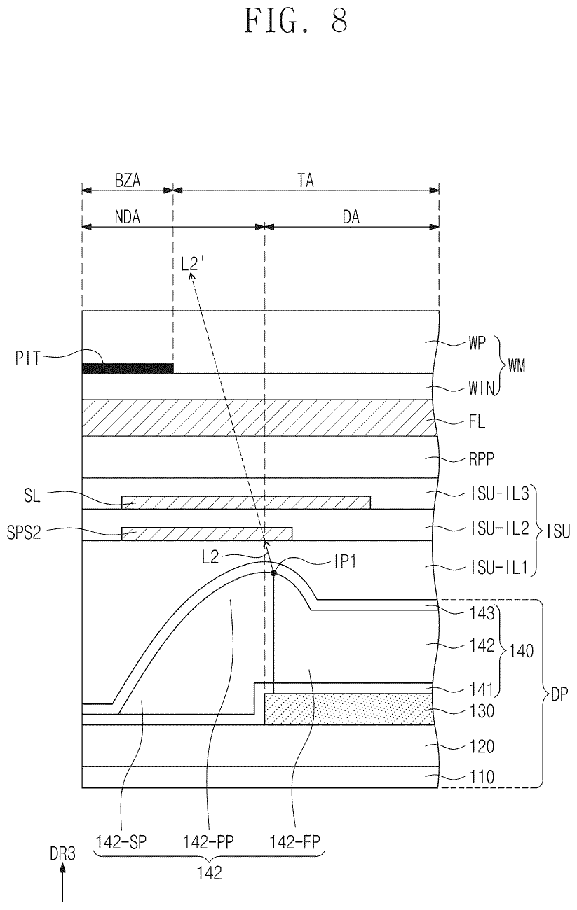

FIG. 7 is a cross-sectional view of a portion of a display device according to one or more embodiments of the present disclosure. FIG. 8 is an enlarged cross-sectional view of a portion of a display device according to one or more embodiments of the present disclosure. FIG. 7 and FIG. 8 illustrates a cross section corresponding to a non-display region NDA and a portion of a display region DA adjacent thereto in a display panel DP. Overlapping description of the components described above with respect to FIG. 5 will not be repeated.

The display device DD according to one or more embodiments includes an optical structure overlapping the protrusion 142-PP. The optical structure may overlap the protrusion 142-PP on a plane, and thus may change a path of light refracted or scattered by the protrusion 142-PP, or may block at least portion of the refracted or scattered light. The display device DD according to one or more embodiments may reduce the amount of the refracted or scattered light due to having the optical structure, so that the likelihood of a stain or the like may be reduced or prevented from occurring in the display region DA adjacent to the non-display region NDA, thereby improving a visibility of the display device DD. The optical structure may be included in the input-sensing unit ISU or the window WM, which is located on the display panel DP. The optical structure may overlap the non-display region NDA.

As illustrated in FIG. 7 and FIG. 8, the input-sensing unit ISU of the display device DD may include a second optical structure SPS2. The second optical structure SPS2 may be located on any one layer among the plurality of sensing insulating layer ISU-IL1, ISU-IL2, and ISU-IL3 that are included in the input-sensing unit ISU. In one or more embodiments, the second optical structure SPS2 may be located on the first sensing insulating layer ISU-IL1. The second optical structure SPS2 may be located in the non-display region NDA, and at least a portion of the second optical structure SPS2 may overlap the protrusion 142-PP of the organic encapsulation layer 142.

The second optical structure SPS2 and the first conductive pattern layer ISU-CL1 may include the same material, and may be formed through the same process. The second optical structure SPS2 and the first conductive pattern layer ISU-CL1 may originate from the same metallic material layer. In one or more embodiments, the metallic material layer may be formed on the first sensing insulating layer ISU-IL1, and then at a location corresponding to the non-display region NDA, the second optical structure SPS2 may be formed by patterning a portion of the metallic material layer so as to correspond to the protrusion 142-PP of the organic encapsulation layer 142.

The second optical structure SPS2 may block a portion of light refracted or scattered by the protrusion 142-PP of the organic encapsulation layer 142, and thus may improve the visibility of the display device DD.

As illustrated in FIG. 8, light L2 generated in the display region DA that is adjacent to the non-display region NDA, and travelling along a third direction DR3 at an early stage, may be refracted at a first point IP1 in an interface between the protrusion 142-PP and the input-sensing unit ISU.

Meanwhile, the organic encapsulation layer 142 including the protrusion 142-PP may be different in refractive index from the input-sensing unit ISU. In a visible light wavelength range of about 380 nm to about 780 nm, the organic encapsulation layer 142 may have a refractive index that is different from a refractive index of at least one among the plurality of sensing insulating layers ISU-IL1, ISU-IL2, or ISU-IL3 (see FIG. 5). In the visible light wavelength range, the refractive index of at least one among the plurality of sensing insulating layers ISU-IL1, ISU-IL2, or ISU-IL3 may be larger than the refractive index of the organic encapsulation layer 142.

At least portion of the light L2 refracted at the first point IP1 may be blocked by the second optical structure SPS2 located above the first point IP1, and thus intensity of light may be reduced. Because the second optical structure SPS2 contains a metallic material, and thus has a low light transmittance, at least portion of the light L2 refracted at the first point IP1 may be blocked, and thus intensity of light L2′ travelling upwards may be reduced. In a display device DD according to one or more embodiments, even if the light L2 emitted in the frontal direction is refracted at the first point IP1, and thus a path of light is changed, the intensity of the light L2′, which is at least partially blocked by the second optical structure SPS2, may be reduced, and thus the display device DD may reduce light refracted or scattered, thereby reducing or preventing the likelihood of a stain or the like from occurring in the display region DA adjacent to the non-display region NDA.

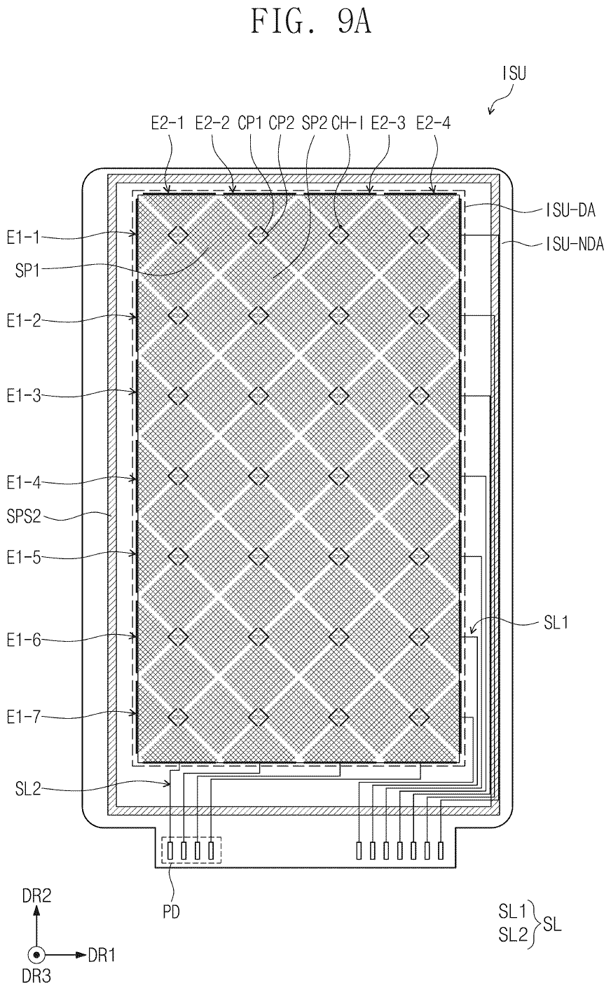

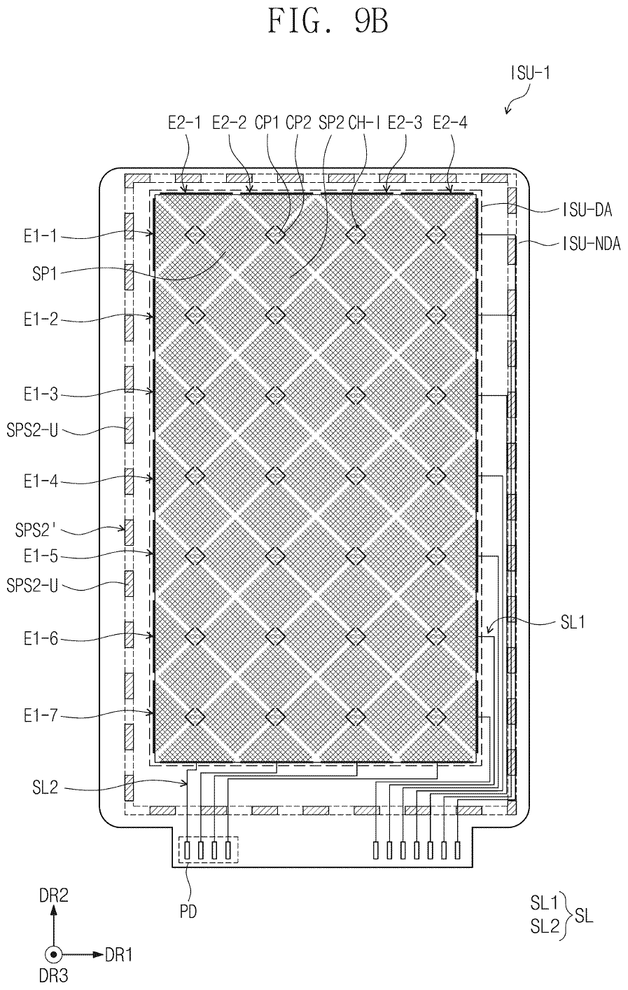

FIG. 9A is a plan view of an input-sensing unit according to one or more embodiments of the present disclosure. FIG. 9B is a plan view of an input-sensing unit according to one or more embodiments of the present disclosure.

Referring to FIG. 7, FIG. 8, and FIG. 9A, an input-sensing unit ISU may include a first sensing insulating layer ISU-IL1, a first conductive pattern layer ISU-CL1, a second sensing insulating layer ISU-IL2, a second conductive pattern layer ISU-CL2, and a third sensing insulating layer ISU-IL3. The first sensing insulating layer ISU-IL1 may be directly located on an encapsulation layer 140.

The first conductive pattern layer ISU-CL1 may include first conductive patterns, and the second conductive pattern layer ISU-CL2 may include second conductive patterns. Hereinafter, the first conductive pattern layer ISU-CL1 and the first conductive patterns are denoted as the same reference numerals and symbols, and the second conductive pattern layer ISU-CL2 and the second conductive patterns are denoted as the same reference numerals and symbols.

Each of the first conductive patterns ISU-CL1 and the second conductive patterns ISU-CL2 may have a single-layered structure or a multi-layered structure in which layers are stacked along a third direction DR3. A conductive pattern having a multi-layered structure may include at least two among transparent conductive layers and metal layers. The conductive pattern having a multi-layered structure may include metal layers containing different metals. The transparent conductive layers may each contain indium tin oxide (ITO), indium zinc oxide (IZO), zinc oxide (ZnO), indium tin zinc oxide (ITZO), PEDOT, a metal nanowire, or graphene. The metal layers may each contain molybdenum, silver, titanium, copper, aluminum, or an alloy thereof.

Each of the first sensing insulating layer ISU-IL1 to the third sensing insulating layer ISU-IL3 may include an inorganic layer or an organic layer. The first sensing insulating layer ISU-IL1 to the third sensing insulating layer ISU-IL3 may include an inorganic layer. The inorganic layer may contain silicon oxide, silicon nitride, or silicon oxynitride.

In one or more embodiments of the present disclosure, at least one among the first sensing insulating layer ISU-IL1 to the third sensing insulating layer ISU-IL3 may be an organic layer. For example, the third sensing insulating layer ISU-IL3 may include an organic layer. The organic layer may contain at least one of an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

The input-sensing unit ISU may include a sensing region ISU-DA and a non-sensing region ISU-NDA adjacent to the sensing region ISU-DA. The sensing region ISU-DA and the non-sensing region ISU-NDA may respectively correspond to the display region DA (see FIG. 3) and the non-display region NDA (see FIG. 3), which are illustrated in FIG. 3.

The input-sensing unit ISU may be located in the sensing region ISU-DA, and may include first electrodes E1-1, E1-2, E1-3, E1-4, E1-5, E1-6, and E1-7 and second electrodes E2-1, E2-2, E2-3, and E2-4, the first and second electrodes being insulated from each other and crossing each other. The input-sensing unit ISU includes signal lines SL located in the non-sensing region ISU-NDA. The signal lines SL may include first group signal lines SL1 electrically connected to the first electrodes E1-1, E1-2, E1-3, E1-4, E1-5, E1-6, and E1-7, and second group signal lines SL2 electrically connected to the second electrodes E2-1, E2-2, E2-3, and E2-4. By a combination of the first conductive patterns ISU-CL1 and the second conductive patterns ISU-CL2, which have been described with reference to FIG. 7, the first electrodes E1-1, E1-2, E1-3, E1-4, E1-5, E1-6, and E1-7, the second electrodes E2-1, E2-2, E2-3, and E2-4, the first group signal lines SL1, and the second group signal lines SL2 may be defined.

Each of the first electrodes E1-1, E1-2, E1-3, E1-4, E1-5, E1-6, and E1-7 and the second electrodes E2-1, E2-2, E2-3, and E2-4 may include a plurality of conductive lines crossing each other. The plurality of conductive lines may define a plurality of openings, and the first electrodes E1-1, E1-2, E1-3, E1-4, E1-5, E1-6, and E1-7 and the second electrodes E2-1, E2-2, E2-3, and E2-4 may have a mesh shape. Each of the plurality of openings may be defined to correspond to a light-emitting region of a display panel DP.

Either of the first electrodes E1-1, E1-2, E1-3, E1-4, E1-5, E1-6, and E1-7 or the second electrodes E2-1, E2-2, E2-3, and E2-4 may be provided as one piece. The first electrodes E1-1, E1-2, E1-3, E1-4, E1-5, E1-6, and E1-7 provided as one piece are illustrated as an example. Each of the first electrodes E1-1, E1-2, E1-3, E1-4, E1-5, E1-6, and E1-7 may include sensing patterns SP1 and intermediate portions CP1. The sensing patterns SP1 and the intermediate portions CP1 may be provided as one piece. A portion of the second conductive patterns ISU-CL2 described above may correspond to the first electrodes E1-1, E1-2, E1-3, E1-4, E1-5, E1-6, and E1-7.

Each of the second electrodes E2-1, E2-2, E2-3, and E2-4 may include sensing patterns SP2 and bridge patterns CP2 (or connecting patterns). Two sensing patterns SP2 adjacent to each other may be connected by two bridge patterns CP2 through a contact hole CH-I penetrating the second sensing insulating layer ISU-IL2 (see FIG. 4), but the number of the bridge patterns is not limited thereto. A portion of the second conductive patterns ISU-CL2 described above may correspond to the sensing patterns SP2. A portion of the first conductive patterns ISU-CL1 described above may correspond to the bridge patterns CP2.

Description is made such that the bridge patterns CP2 are formed from the first conductive patterns ISU-CL1 illustrated in FIG. 7, and the first electrodes E1-1, E1-2, E1-3, E1-4, E1-5, E1-6, and E1-7 and the sensing patterns SP2 are formed from the second conductive patterns ISU-CL2 illustrated in FIG. 7, but one or more embodiments of the present disclosure is not limited thereto. The first electrodes E1-1, E1-2, E1-3, E1-4, E1-5, E1-6, and E1-7 and the sensing patterns SP2 may be formed from the first conductive patterns ISU-CL1 illustrated in FIG. 4, and the bridge patterns CP2 may be formed from the second conductive patterns ISU-CL2 illustrated in FIG. 7.

One of the first group signal lines SL1 or the second group signal lines SL2 transfers a transmission signal for sensing an external input from an external circuit, and the other of the first group signal lines SL1 or the second group signal lines SL2 transfers, to the external circuit, a capacitance change between the first electrodes E1-1, E1-2, E1-3, E1-4, E1-5, E1-6, and E1-7 and the second electrodes E2-1, E2-2, E2-3, and E2-4 as a reception signal. Each of the first group signal lines SL1 and the second group signal lines SL2 may be connected to a sensing pad PD, and may receive a transmission signal transferred from the external circuit, or may transfer a capacitance change between the first electrodes E1-1, E1-2, E1-3, E1-4, E1-5, E1-6, and E1-7 and the second electrodes E2-1, E2-2, E2-3, and E2-4 to the external circuit through the sensing pad PD. In a plan view, the sensing pads PD may be located in a portion corresponding to a lower end of the second base region AA2 of the display panel DP. The circuit board MB (see FIG. 1B) described above may be electrically connected to the sensing pads PD through an anisotropic conductive adhesive layer.

A portion of the second conductive patterns ISU-CL2 described above may correspond to the first group signal lines SL1 and the second group signal lines SL2. As illustrated in FIG. 7, a portion of the second conductive patterns ISU-CL2 may correspond to a signal line SL and may be located on the second sensing insulating layer ISU-IL2. However, one or more embodiments of the present disclosure is not limited thereto, and the signal line SL may have a multi-layered structure that includes a first layer line located on the first sensing insulating layer ISU-IL1, and a second layer line located on the second sensing insulating layer ISU-IL2.

Referring to FIG. 7 and FIG. 9A, a second optical structure SPS2 may be located in the non-sensing region ISU-NDA corresponding to the non-display region NDA, and may have a shape surrounding the sensing region ISU-DA corresponding to the display region DA. In one or more embodiments, the second optical structure SPS2 may have a closed curve shape entirely surrounding the sensing region ISU-DA on a plane. However, one or more embodiments of the present disclosure is not limited thereto, and the second optical structure SPS2 may have a shape surrounding a portion of the sensing region ISU-DA, and not surrounding the remaining portion of the sensing region ISU-DA.

Referring to FIG. 7 and FIG. 9B, a second optical structure SPS2′ included in an input-sensing unit ISU-1 may include a plurality of unit optical structures SPS2-U located in a non-sensing region ISU-NDA that corresponds to the non-display region NDA. The plurality of unit optical structures SPS2-U may be located to be spaced apart from each other. The plurality of unit optical structures SPS2-U may be spaced apart from each other at intervals (e.g., predetermined intervals), and may be arranged to surround at least a portion of a sensing region ISU-DA.

Referring to FIG. 7 and FIG. 9A again, the second optical structure SPS2 may be located in the non-sensing region ISU-NDA corresponding to the non-display region NDA, and may overlap a portion of the signal line SL on a plane. A portion of the second optical structure SPS2 may overlap the signal line SL, and the remaining portion of the second optical structure SPS2 may not overlap the signal line SL.

According to a display device of one or more embodiments of the present disclosure, dead space may be reduced or minimized, and a stain or the like may be reduced or prevented from occurring in a display region adjacent to a non-display region, and therefore, the display device may have an improved visibility.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the technical scope of the present disclosure is not limited to the contents described in the detailed description of the specification, but should be defined by the accompanying claims.

What is claimed is:

1. A display device comprising:
a display panel defining a display region and a non-display region, and comprising a base layer, a light-emitting element layer above the base layer and comprising a light-emitting element, and an organic encapsulation layer above the light-emitting element and comprising a protrusion protruding along a thickness direction of the display panel, at least partially overlapping the display region, and configured to refract a portion of light generated in the display region;
an input-sensing unit above the display panel, and comprising a sensing electrode overlapping the display region, and a signal line connected to the sensing electrode; and
a window above the input-sensing unit, and comprising an optically transparent base substrate, the input-sensing unit or the window comprising an optical structure overlapping the protrusion.

2. The display device of claim 1, wherein the window comprises a first optical structure protruding from the base substrate.

3. The display device of claim 2, wherein the base substrate is integral with the first optical structure.

4. The display device of claim 1, wherein the window further comprises:
a window protective layer above the base substrate; and
a printed layer on the window protective layer and overlapping the non-display region.

5. The display device of claim 1, wherein the input-sensing unit comprises:
a first sensing insulating layer above the encapsulation layer;
a first conductive pattern layer above the first sensing insulating layer;
a second sensing insulating layer above the first conductive pattern layer; and
a second conductive pattern layer above the second sensing insulating layer.

6. The display device of claim 5, wherein the input-sensing unit comprises a second optical structure below the first sensing insulating layer, and overlapping the protrusion.

7. The display device of claim 6, wherein the second optical structure is in the non-display region and has a closed curve shape surrounding the display region in plan view.

8. The display device of claim 6, wherein the second optical structure comprises unit optical structures spaced apart from each other, and arranged in the non-display region to surround the display region in plan view.

9. The display device of claim 5, wherein the sensing electrode comprises sensing patterns above the second sensing insulating layer, and
wherein the signal line is above the second sensing insulating layer.

10. The display device of claim 1, further comprising an anti-reflective layer between the input-sensing unit and the window.

11. The display device of claim 10, further comprising an intermediate layer between the anti-reflective layer and the window, and having a refractive index that is larger than a refractive index of the base substrate.

12. The display device of claim 1, wherein the input-sensing unit further comprises at least one sensing insulating layer having a refractive index that is larger than a refractive index of the organic encapsulation layer.

13. The display device of claim 1, wherein the organic encapsulation layer further comprises:
a flat portion overlapping the display region; and
an inclined portion overlapping the non-display region, and
wherein the protrusion is between the flat portion and the inclined portion.

14. The display device of claim 1, wherein the encapsulation layer further comprises:
a first inorganic encapsulation layer below the organic encapsulation layer; and
a second inorganic encapsulation layer above the organic encapsulation layer, and contacting the first inorganic encapsulation layer.

15. A display device comprising:
a display panel defining a display region and a non-display region, and comprising a base layer, a light-emitting element layer above the base layer and comprising a light-emitting element, and an organic encapsulation layer above the light-emitting element and comprising a protrusion protruding along a thickness direction of the display panel and partially overlapping the display region;
an input-sensing unit above the display panel, and comprising a sensing electrode overlapping the display region, and a signal line connected to the sensing electrode; and
a window above the input-sensing unit, and comprising an optically transparent base substrate, and a first optical structure protruding from the base substrate in a direction adjacent to the input-sensing unit and overlapping the protrusion.

16. The display device of claim 15, wherein the base substrate is integral with the first optical structure.

17. The display device of claim 15, further comprising an intermediate layer between the input-sensing unit and the window, and having a refractive index that is larger than a refractive index of the base substrate.

18. A display device, comprising:
a display panel defining a display region and a non-display region, and comprising a base layer, a light-emitting element layer above the base layer and comprising a light-emitting element, and an organic encapsulation layer above the light-emitting element and comprising a protrusion protruding along a thickness direction of the display panel and at least partially overlapping the display region;
an input-sensing unit above the display panel and comprising a first sensing insulating layer above the encapsulation layer, a second sensing insulating layer above the first sensing insulating layer, and a second optical structure above the first sensing insulating layer and overlapping the protrusion; and
a window above the input-sensing unit and comprising an optically transparent base substrate.

19. The display device of claim 18, wherein the input-sensing unit further comprises:
a sensing electrode overlapping the display region and comprising sensing patterns above the second sensing insulating layer; and
a signal line connected to the sensing electrode.

20. The display device of claim 18, wherein a refractive index of the first sensing insulating layer is larger than a refractive index of the organic encapsulation layer.
